(19) United States
(12) Patent Application Publication
(10) Pub. No.: US 2007/0155161 A1
(43) Pub. Date: Jul. 5, 2007

(54) Selective removal of sacrificial light absorbing material over porous dielectric

(76) Inventors: Vijayakumar S. Ramachandrarao, Portland, OR (US); Kim-Khanh K. Ho, Fremont, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/322,898

(22) Filed: Dec. 30, 2005

(51) Int. Cl. H01L 21/20; H01L 21/4763

(52) U.S. Cl. 438/622

(57) ABSTRACT

A method of forming a semiconductor device. The method comprises forming a conductive layer on a substrate, forming a porous dielectric layer on the conductive layer, and forming a first etched region by removing a first portion of the porous dielectric layer. The first etched region is then filled with a sacrificial light absorbing material. A layer of photoresist is then patterned to define a second region to be etched. A second region is then etched by removing part of the sacrificial light absorbing material and a second portion of the porous dielectric layer. The layer of photoresist is then removed. The remaining portions of the sacrificial light absorbing material is then removed selectively using an anhydrous solvent comprising fluoride and a solvent having molecules with at least one —OH group and three to six carbons, wherein the sacrificial light absorbing material is selectively removed over the porous dielectric layer.

### FIELD

An embodiment of the present invention relates to making semiconductor devices, more particularly, to a method for selectively removing a sacrificial light absorbing material over a porous dielectric to form interconnects.

### BACKGROUND

Integrated circuits (ICs) have evolved into complex devices that can include millions of components (e.g., transistors, capacitors and resistors) on a single chip. The evolution of chip designs continually requires faster circuitry and greater circuit density. The demands for greater circuit density necessitate a reduction in the dimensions of the integrated circuit components.

A dual damascene process is used to create the multi-level, high density metal interconnections needed for advanced, high performance ICs. Dual damascene metal interconnects enable reliable low cost production of ICs. Typically, a first etched region (e.g., a via or trench) is filled with a sacrificial light absorbing material (“SLAM”), after that region has been formed within a dielectric layer. A SLAM may comprise a dyed spin-on-glass (“SOG”) that has dry etch properties similar to those of the dielectric layer and light absorbing characteristics that enable the substrate to absorb light during lithography. After the first etched region is filled with the SLAM, a second etched region (e.g., a trench if the via is already formed or a via if the trench is already formed) is formed within the dielectric layer. Most of the SLAM may be removed as the second etched region is formed. Remaining portions of the SLAM are removed by a subsequent wet etch step.

The dielectric materials used to form ICs typically have a low dielectric constant. Some dielectric materials are carbon doped oxide (“CDO”) and in many instances, are made of porous materials (p-CDO), instead of silicon dioxide to separate metal lines and yield a device having reduced propagation delay, cross-talk noise and power dissipation. Current methods used to remove SLAM over CDO can be damaging to p-CDO and thus, can physically and electrically damage the device.

Accordingly, there is a need for an improved process for making a semiconductor device that includes a dual damascene interconnect, which employs a SLAM and a porous dielectric with a low dielectric constant (e.g., lower than nonporous CDO) layer to make such a device.

### BRIEF DESCRIPTION OF THE DRAWINGS

The embodiments of the present invention are illustrated by way of example and not by way of limitation in the figures of the accompanying drawings in which like references indicate similar elements. The invention may best be understood by referring to the following description and accompanying drawings that are used to illustrate embodiments of the invention. It should be noted that references to “an” or “one” embodiment of the invention in this disclosure are not necessarily to the same embodiment, and they mean at least one. In the drawings:

FIGS. 1-9 illustrate cross-sections that reflect structures that may result after certain steps are used to make a semiconductor device that has a dual damascene interconnect, following one embodiment of the method of the present invention; and

FIG. 10 illustrates an example of a caging concept of fluoride ion.

### DETAILED DESCRIPTION

In the following description, numerous specific details are set forth to provide a thorough understanding of the invention. However, it is understood that embodiments of the invention may be practiced without these specific details. In other instances, well-known circuits, structures and techniques have not been shown in detail in order not to obscure the understanding of this description. Exemplary embodiments are described with reference to specific configurations and techniques. Those of ordinary skill in the art will appreciate the various changes and modifications to be made while remaining within the scope of the appended claims. Additionally, well known elements, devices, components, circuits, process steps and the like are not set forth in detail.

A method of forming a semiconductor device is described. That method comprises the following steps. First, a conductive layer is formed on a substrate. A dielectric layer is then formed on the conductive layer, followed by forming a first etched region by removing a first portion of the dielectric layer. That first etched region is filled with a sacrificial light absorbing material (SLAM) that has dry etch properties similar to those of the dielectric layer. The dielectric layer may comprise a carbon doped oxide, may be of a low-k dielectric constant, may have high porosity (e.g., 10-50% porosity), or may have higher porosity than the SLAM. A layer of photoresist is then deposited and patterned to define a second region to be etched. A second etched region is formed by removing part of the sacrificial light absorbing material and a second portion of the dielectric layer. The resulting device is then exposed to plasma generated from a forming gas, to remove the remaining portions of the photoresist, followed by exposing it to an etching solution that contains fluoride ions in a solvent that is predominantly non-aqueous for removing the remaining portions of the sacrificial light absorbing material. The non-aqueous solvent comprises —OH groups and carbon chains. The number of the —OH groups and the carbon chain length is controlled so that the etch rate and etch selectivity of the SLAM relative to the dielectric layer is controlled or tailored.

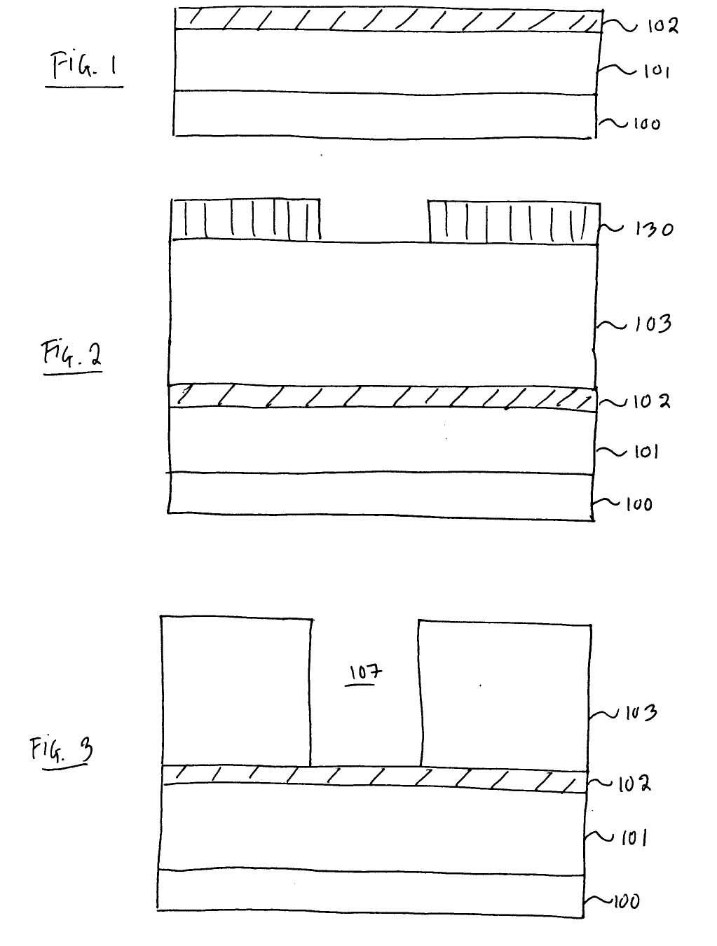

FIGS. 1-9 illustrate one embodiment of the method of the present invention. In that embodiment, first conductive layer 101 is formed on substrate 100. Substrate 100 may be any surface, generated when making an integrated circuit, upon which a conductive layer may be formed. Substrate 100 thus may include, for example, active and passive devices that are formed on a silicon wafer such as transistors, capacitors, resistors, diffused junctions, gate electrodes, local interconnects, etc. Substrate 100 also may include insulating materials that separate such active and passive devices from the conductive layer or layers that are formed on top of them, and may include previously formed conductive layers.

Conductive layer 101 may be made from materials conventionally used to form conductive layers for semiconductor devices. In a preferred embodiment, conductive layer 101 includes copper, and is formed using a conventional copper electroplating process. Although copper is preferred, other conducting materials, which may be used to make a semiconductor device, may be used instead. Conductive layer 101 may be planarized, after it is deposited, using a chemical mechanical polishing (“CMP”) step.

After forming conductive layer 101 on substrate 100, barrier layer 102 is formed on conductive layer 101. Barrier layer 102 will serve to prevent an unacceptable amount of copper, or other metal, from diffusing into dielectric layer 103. Barrier layer 102 also acts as an etch stop to prevent subsequent via and trench etch steps from exposing conductive layer 101 to subsequent cleaning steps. Barrier layer 102 preferably is made from silicon nitride, but may be made from other materials that can serve such functions, e.g., silicon carbide or cobalt, as is well known to those skilled in the art.

A chemical vapor deposition process may be used to form barrier layer 102. Barrier layer 102 should be thick enough to perform its diffusion inhibition and etch stop functions, but not so thick that it adversely impacts the overall dielectric characteristics resulting from the combination of barrier layer 102 and dielectric layer 103. FIG. 1 illustrates a cross-section of the structure that results after conductive layer 101 and barrier layer 102 have been formed on substrate 100.

Dielectric layer 103 is then formed on top of barrier layer 102. In the method of the present invention, dielectric layer 103 comprises a porous carbon doped oxide (“p-CDO”). Those of ordinary skill in the art will appreciate that such a material may be deposited on the surface of barrier layer 102 using a conventional plasma enhanced chemical vapor deposition (“PECVD”) process. Dielectric layer 103 preferably consists essentially of a CDO that includes between about 5 and about 30 atom % carbon, and preferably has a thickness of between about 300 and about 3,000 nanometers. Alternatively, dielectric layer 103 has a porosity approximately between 10-50%. Alternatively, dielectric layer 103 has a low dielectric constant (e.g., 1.9-2.7).

After forming dielectric layer 103, a photoresist layer 130 is patterned on top of it to define a via formation region for receiving a subsequently formed conductive layer that will contact conductive layer 101. Photoresist layer 130 may be patterned using conventional photolithographic techniques, such as masking the layer of photoresist, exposing the masked layer to light, then developing the unexposed portions. The resulting structure is shown in FIG. 2.

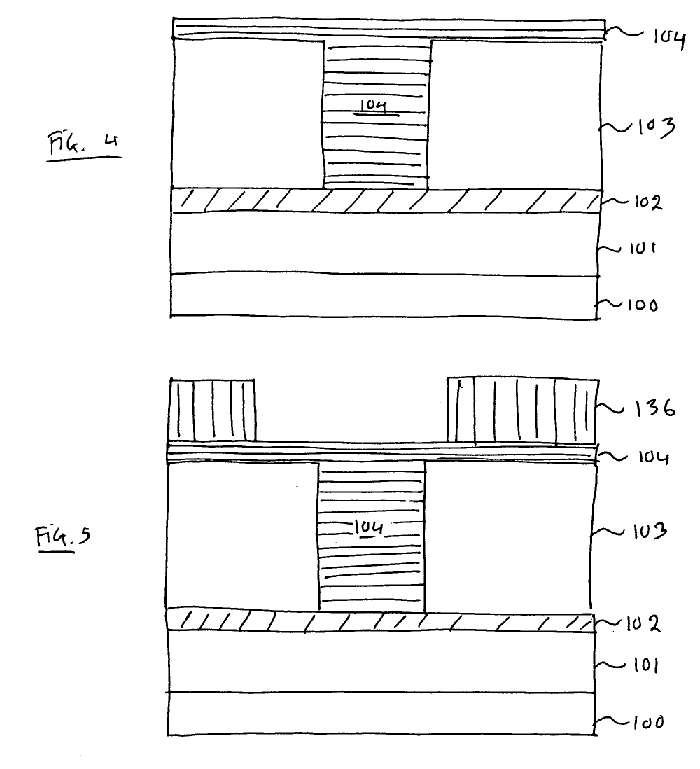

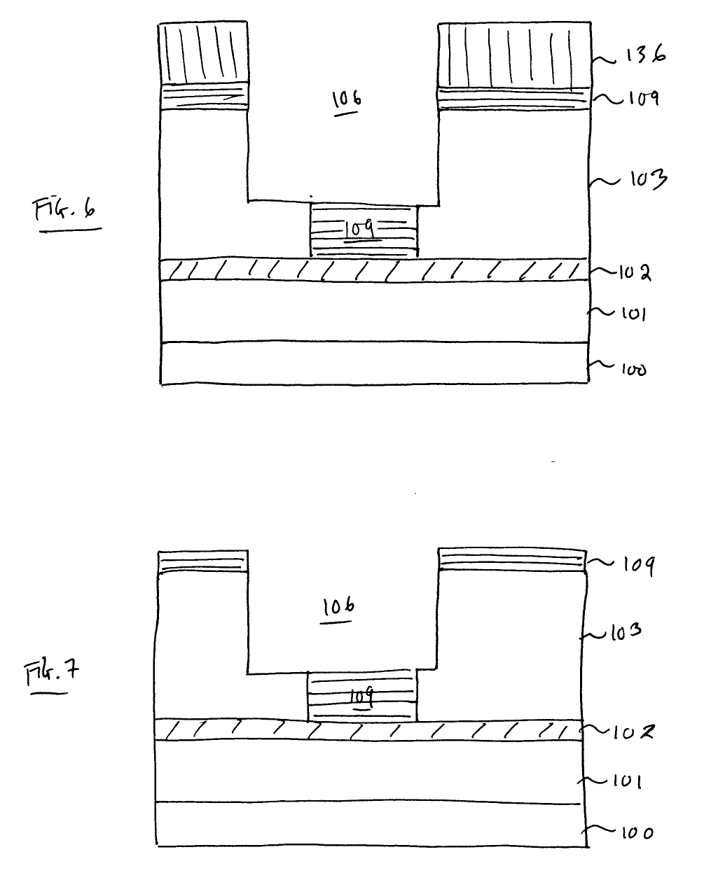

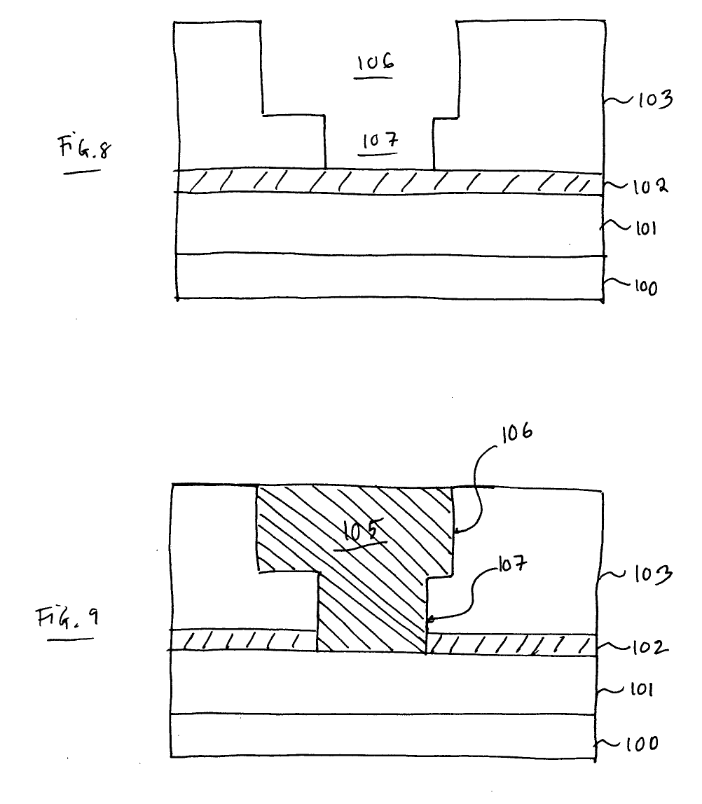

After photoresist layer 130 is patterned, via 107 is etched through dielectric layer 103 down to barrier layer 102, barrier layer 102 acting as an etch stop. Conventional process steps for etching through a dielectric layer may be used to etch the via, e.g., a conventional anisotropic dry oxide etch process. An isotropic or anisotropic forming gas ash may then be applied at an appropriate temperature and pressure to remove the photoresist. Other methods and/or materials can also be used, for example, carbon monoxide based plasma, carbon dioxide based plasma, and water vapor based plasma. A via clean step may follow to produce the structure shown in FIG. 3. Via 107 may be cleaned by using a conventional hydrogen fluoride (“HF”) in ethylene glycol, or HF in deionized water, based wet etch process, as is well understood by those skilled in the art. In many embodiments, the cleaning step is not necessary. For example, the via 107 is obtained after the ashing step with no additional cleaning step required. After via 107 is formed through dielectric layer 103, via 107 is filled with sacrificial light absorbing material (“SLAM”) 104, generating the structure shown in FIG. 4. SLAM 104 has dry etch properties similar to those of dielectric layer 103 to form a rectangular trench, but may be wet etched at a rate that is significantly faster than the rate at which dielectric layer 103 may be wet etched. The high selectivity of SLAM 104 to the wet etch enables removal of that material from the surface of the device, as well as from inside via 107, without causing a significant amount of dielectric layer 103 to be removed at the same time.

Preferably, SLAM 104 comprises a dyed spin-on-glass (“SOG”) that is deposited by spin coating between about 500 and about 3,000 angstroms of the material onto the surface of the device. SLAM 104 can also be a dyed spin-on-polymer as is known in the art. Although only a thin layer will remain on the surface of the device, such a spin coating process should cause SLAM 104 to completely fill via 107. In addition, SLAM 104 should uniformly fill via 107. Such a uniform fill characteristic minimizes void formation, which could jeopardize the integrity of the filling and/or may expose the underlying silicon nitride layer—for an undesirable extended period of time—to the etch chemistry used to form the trench. Using a dyed SOG for SLAM 104 should reduce, or even eliminate, substrate reflectivity at DUV wavelengths (e.g., at 157, 193 or 248 nm). It is to be noted that SLAM that is spun cast has SiOH groups (polar groups) in it while p-CDO and CDO dielectric layers do not possess these polar groups in them due to the nature of its deposition (PECVD).

The dyed SOG should provide the following properties. It may be dry etched at substantially the same rate that dielectric layer 103 is dry etched. It may be wet etched at a significantly faster rate than dielectric layer 103 is wet etched. It may absorb light such that substrate 100 is rendered substantially non-reflective when exposed to light (e.g., at 157, 193 or 248 nm) used to pattern a photoresist layer to define the trench, and it may completely and uniformly fill via 107. Both Honeywell, Inc., and Tokyo Ohka Kogyo Co. Ltd., have made a dyed SOG material that has such properties by changing the base solvent used to make one of their commercial SOG products, then selecting an appropriate dye.

After filling via 107 with SLAM 104, photoresist layer 136 is applied on top of SLAM 104, then patterned to define a trench formation region. Photoresist layer 136 may be patterned using conventional photolithographic techniques. The resulting structure is shown in FIG. 5. Following that photoresist patterning step, trench 106 is etched into dielectric layer 103 to form the structure shown in FIG. 6.

The etching process is applied for a time sufficient to form a trench having the desired depth. The etch chemistry chosen to etch trench 106 preferably should remove SLAM 104 at about the same rate that it removes dielectric layer 103. Trench 106 may be etched using the same equipment (or another equipment) and similar etch chemistry that had been used previously to etch via 107. By filling via 107 with a sacrificial light absorbing material having dry etch characteristics like those of CDO containing dielectric layer 103, the trench lithography process effectively applies to a substantially “hole-free” surface, similar to one without vias. By selecting an appropriate dyed SOG material for SLAM 104, and an appropriate plasma etch chemistry, trench 106 may be etched into dielectric layer 103 at approximately the same rate that SLAM 104 is removed. Because such a process protects the underlying barrier layer 102 as trench 106 is etched, it permits use of a trench etch chemistry that produces superior trench and via profiles without having to consider its effect on the selectivity between dielectric layer 103 and barrier layer 102. For example, when barrier layer 102 comprises silicon nitride or silicon carbide, this process enables use of an etch chemistry to etch the trench that does not provide a high selectivity to CDO over silicon nitride or silicon carbide.

After trench 106 is etched, the remaining portion of photoresist 136 and the remaining portion 109 of the SLAM must be removed. In one embodiment, a low temperature, low-pressure oxygen based ashing step is used to remove photoresist 136, followed by applying a wet etch process to remove remaining residues. In one embodiment, a forming gas is used to remove photoresist layer 136. The forming gas preferably comprises a plasma that contains hydrogen. Such a hydrogen containing plasma may comprise hydrogen combined with any of the following gases: nitrogen, helium, argon, xenon, neon, or krypton. Preferably, such a forming gas includes at least about 2% hydrogen. In a particularly preferred embodiment, such a forming gas includes about 4% hydrogen in nitrogen. The equipment and operating conditions for using a forming gas to remove photoresist layer 136 may be those typically used in this type of plasma ashing process. Such a process may remove the photoresist in either an isotropic or anisotropic fashion, and may be applied over a wide range of temperatures and pressures. Removal of photoresist layer 136 generates the structure shown in FIG. 7.

It is to be appreciated that although the embodiments discuss mainly that a via is formed before a trench is formed, the process may involve forming a trench prior to forming the vias without exceeding the scope of the embodiments of the present invention.

Following such a photoresist removal step, remaining portions 109 of the SLAM must be removed. It is to be understood that when the word “SLAM” is used, it can be generally referred to the portion 109 of the SLAM or other remaining SLAM portion not illustrated herein. In the embodiments of the present invention, the remaining portion 109 of the SLAM is removed using a wet etching process. A fluoride containing non-aqueous solution is used to remove the SLAM using a wet etching process. In one embodiment, the fluoride containing non-aqueous solution selectively removes the SLAM over a porous dielectric layer without affecting the porous dielectric layer physically and without electrically damaging the dielectric layer that may be p-CDO. In some instances, some minimal electrical damage may occur but irreversible and fully recovered. For selectively removing the SLAM over the porous dielectric layer (e.g., pCDO dielectric layer), the fluoride containing non-aqueous solution comprises a solvent having —OH groups and carbon chains with the number of carbon being selected so that the SLAM is etched at a faster rate than the porous dielectric layer.

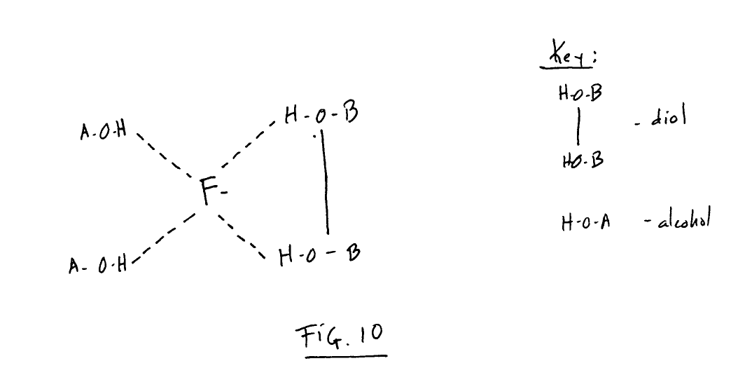

In a liquid medium containing fluoride ions & solvents, each fluoride ion coordinates with four polar side-groups, be it from the same solvent or different e.g., —OH side groups of a solvent molecule. When a fluoride compound is mixed into a polar protic solvent or an anhydrous solvent such as alcohol, glycol, or glycol ether, the fluoride ion is “caged” by the solvent molecules. For example, as illustrated in FIG. 10, in one example, a fluoride ion is shown to be caged coordinating with the —OH groups of the solvent molecules and the hydrocarbon ends denoted by A & B form the shell of the caged complex rendering the fluoride less reactive. A solvent containing a primary alcohol or a diol (with 2 —OH groups) will provide such efficient caging. The net reactivity of the fluoride ion is controlled by the degree of caging of the fluoride ion by the solvent molecules. An optimal solvent to be mixed with a fluoride compound to form an etching solution for selectively removing the SLAM over the dielectric layer is one that provides molecules that efficiently cage the fluoride ion to provide a sufficiently stable solution with the fluoride ions able to interact with the SiOH groups that are present only in the SLAM. When the coordinated complex of fluoride ions and the —OH groups of the solvent molecules come in the vicinity of the polar bonds like SiOH of the SLAM, the coordination is disrupted and the fluoride ions are freed to react with the local Si—O—Si bonds of the SLAM, thereby etching/dissolving it.

In many embodiments, to remove the SLAM, the etching solution must selectively remove (or etch) the SLAM portion 109 (or other remaining SLAM needed to be removed) without affecting the dielectric layer 103 (ranging between CDO & p-CDO). Alternatively, the etching solution is formulated to remove the SLAM portion 109 at an etch rate is higher than that of it removes the dielectric layer 103, thus, providing selectivity of removing the SLAM over the dielectric layer.

In one embodiment, a solvent type (such as a primary alcohol or diol and the number of carbon in the solvent molecules) is selected so as to control the selectivity of removing the SLAM over a p-CDO (porous dielectric layer). In one embodiment, the solvent for the etching solution is selected so that the SLAM is selectively etched at a much higher rate than that of the p-CDO thus giving the etching selectivity to the SLAM over the p-CDO. In one embodiment, the higher etch rate of SLAM portion 109 over the dielectric layer 103 is achieved by choosing a solvent having molecules that sufficiently cage the fluoride ions to form a sufficiently stable etching solution which in turn is obtained by controlling the number of —OH groups in the solvent molecules, controlling the length of the carbon chain of the solvent molecules, by having little to no water in the solution and absence of other ionic species in the solution that can disrupt coordinated cage of F-ions.

As mentioned, e.g., FIG. 10, when mixed with a solvent, each fluoride ion of a fluoride compound can typically be caged by four solvent molecules. In one example as shown in FIG. 10, the fluoride compound is mixed in a solvent that comprises primary alcohol molecules and diol molecules. In one instance, two —OH groups from two primary alcohol molecules and two —OH groups from a single diol molecule cage a fluoride ion. In many embodiments, the solvent includes only a primary alcohol or a diol.

Solvent molecules containing only one (1) —OH group such as primary alcohol molecules have a good caging effect on the fluoride ions and yet readily free the fluoride ion to allow the fluoride ion to react with the SLAM and effectively and selectively remove the SLAM over the porous dielectric layer. To be efficient in selectively removing the SLAM, the solvent molecules and fluoride mixture must be able to etch the SLAM at a faster rate than the dielectric layer. When the mixture is able to etch the SLAM at a faster rate, the etching time & temperature can be controlled so that the SLAM is selectively removed, and the etching is stopped to prevent the etching of the dielectric layer. The etching solution that comprises one (1) —OH group solvent molecules and fluoride compound removes the SLAM layer more selectively in that the SLAM layer is removed at a higher etch rate than the dielectric layer (e.g., 50-200 times higher). Thus, the selectivity of removing the SLAM can be controlled or optimized by selecting a solvent with at least one (1) —OH group such as a primary alcohol or diol to be mixed with a fluoride containing compound.

In addition, the selectivity of removing the SLAM can also be controlled or optimized by selecting an —OH containing solvent having molecules that have a short carbon chain or a small number of carbon in the solvent molecules. In one embodiment, the —OH containing solvent includes molecules with four to six carbons. In one embodiment, the solvent to be mixed with the fluoride containing compound is a primary alcohol with molecules that has four to six carbons. In another embodiment, the solvent to be mixed with the fluoride containing compound is a diol with molecules having two (2) —OH groups and four (4) to six (6) carbons. In yet another embodiment, the solvent is a mixture of both a primary alcohol and a diol each having molecules with four to six carbons and —OH groups. Primary alcohol solvent with a chain of one to three carbons may be too flammable for practical purposes. Primary alcohols having longer carbon chains tend to increase the etch rate of the dielectric layer, thus, decreasing the selectivity of SLAM removal. Long carbon chain (higher number of carbons) more than five (5) alcohols may cause a steric effect hindering the coordination of 4 OH-group containing solvent molecules with the fluoride ion. In other words, the dangling solvent chains of the longer alcohol molecule cause local crowding around the fluoride ion preventing efficient coordination. This results in poorer caging of the fluoride ions and thereby increasing the etch rate of the p-CDO and hence reducing the SLAM removal selectivity.

Additionally, solvent molecules with 2 —OH groups (diols) also appear to cage F-ions effectively and the role of the number of C linkages or length of the hydrocarbon part in the solvent is important. Each solvent molecule can supply 2 —OH groups to effectively bind with F-ion. If the solvent molecule is long (8 carbon) it would lead to a very good caging of the F-ion to the point the SLAM is not removed at all. A solvent with a chain length of 2-6 carbons has been found to be an optimal solvent for the etching solution.

An optimal solvent for a fluoride compound to selectively remove the SLAM would be one that includes at least one —OH groups and carbon chain length that minimizes steric effects for the interaction of solvent molecules with the fluoride ions (unlike long chained alcohols); one that has a good etch rate on SLAM (unlike long chained diols). In one embodiment, a optimal solvent comprises a mixture of a four-carbon alcohol (butanol) and a four-carbon glycol (1,4-butanediol).

In one embodiment, the solvent to be mixed with the fluoride containing compound does not include an ether based solvent and does not include a hydrocarbon molecule (like alkanes). A solvent with just —O— group (like tetrahydrofuran) may not be optimal for the solvent since it may not cage the fluoride ion as desired. Furthermore, using an ether based solvent tends to reduce selectivity of etching the SLAM since both the SLAM and the dielectric layer are etched at substantially the same rate with the ether based solvent. Additionally, a hydrocarbon solvent with no —OH groups tend to cause both the SLAM and the dielectric layer to be etched at a high rate, thus, selectivity of etching only the SLAM is reduced.

In one embodiment, a wet etch process is used to remove the SLAM with an etching solution comprising a mixture of butanol and butanediol, which is further mixed with HF. In one embodiment, the butanol and butanediol mixture has a 50:50 ratio and the butanol-butanediol mixture and the HF have a ratio between 1:16 to 1:500. The ratio of the butanol-butanediol mixture to the HF is selected so that the SLAM portion 109 can be removed at a substantially faster rate than the dielectric layer 103 (e.g., 50-200 times faster).

Numerous different combination of alcohol comprising solvents can be used. For instance, the alcohol solvent can include more primary alcohol than diol so long as the etching solvent does not reach flash point that is impractical to use in the wet etch process to remove the SLAM portion 109. The etching alcohol solvent can also include more of the diol molecules than the primary alcohol so long as the etch rate of the SLAM is still optimal or desirable. In one embodiment, the etching solvent has a ratio of 50% primary alcohol and 50% diol and the etching solvent is mixed with the HF solution with a ratio approximately between 6:1-500:1 (etching solvent: HF). In an alternative embodiment, sulphur containing solvents (like thiols) are used in place of alcohol solvents to attain the same goals previously discussed for the etching solution.

In one embodiment, the etching solution comprises at least one fluoride-containing compound, at least one organic solvent, no water to very minimal water, and optionally at least one chelating agent. In yet another embodiment, the etching solution comprises at least one fluoride-containing compound, optionally at least one organic solvent, optionally an acid-base buffer, optionally at least one chelator/passivation agent, and no water to very minimal water, if any. In one embodiment, the etching solution includes at least one fluoride-containing compound, at least one organic solvent, no water to very minimal water, and optionally, at least one chelator/passivation agent, present in the following ranges based on the total weight of the compositions:

| Component of | % by weight |
|---|---|
| Fluoride-containing compound(s) | about 0.01% to about 5% |
| Organic solvent(s) | about 90.0% to about 99.9% |
| Chelator/passivation agent(s) | about 0.01% to about 99.9% |
| Water | about 0% to about 5.0% |

In one embodiment, the etching solution preferably has a pH value less than about 5, more preferably less than about 4. In another embodiment, the etching solution includes additional components, including active as well as inactive ingredients, e.g., surfactants, stabilizers, dispersants, anti-oxidants, penetration agents, adjuvants, additives, fillers, excipients, etc.

Preferably, in one embodiment the etching solution includes the following components:

| Component of | % by weight |
|---|---|
| Fluoride-containing compound(s) | about 0.01% to about 5.0% |
| Organic solvent(s) | about 90.0% to about 99.9% |
| Water | about 0% to about 5.0% |

wherein percentages of the components are percentages by weight, based on total weight of the composition, and wherein the total of the weight percentage of such components of the composition does not exceed 100 weight %.

Suitable sources of fluoride-containing compounds include, but are not limited to, hydrogen fluoride, ammonium fluoride, and triethanolamine hydrofluoric acid salt. Alternatively, salts of bifluorides may be used, including ammonium bifluoride ((NH₄) HF₂) and tetraalkylammonium bifluorides ((R)₄NHF₂, where R is methyl, ethyl, propyl, butyl, phenyl, benzyl, or fluorinated C₁-C₄ alkyl groups). Combinations of two or more fluoride species are also contemplated herein. In a preferred embodiment, the fluoride-containing compound includes hydrogen fluoride. Notably, hydrogen fluoride is typically shipped with residual quantities of water and as such, water may be present in the removal composition even though no water is intentionally added thereafter. Alternatively, gaseous anhydrous hydrogen fluoride may be used so that the only water present in the formulation is trace water originating from the solvents. Anhydrous hydrogen fluoride-containing formulations typically display better metal and dielectric compatibility than water-containing formulations.

Suitable solvent species for embodiments of the present invention include, without limitation: tetramethylene sulfone; straight-chained or branched C₁-C₆ alcohols including, but not limited to,- methanol, ethanol, 1-propanol, 2-propanol, 1-butanol, 2-butanol, t-butanol, and 1-pentanol; glycols such as ethylene glycol, propylene glycol (1,2-propanediol), tetramethylene glycol (1,4-butanediol) and neopentyl glycol; or glycol ethers such as diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether, triethylene glycol monobutyl ether, propylene glycol methyl ether, dipropylene glycol methyl ether, tripropylene glycol methyl ether, propylene glycol n-propyl ether, dipropylene glycol n-propyl ether, tripropylene glycol n-propyl ether, propylene glycol n-butyl ether, dipropylene glycol n-butyl ether, and tripropylene glycol n-butyl ether. Other solvents that are useful are typical polar solvents such dimethylacetamide, formamide, dimethylformamide, 1-methyl-2-pyrrolidinone, dimethyl sulfoxide, thiols and other polar solvents. Combinations of two or more solvent species are also contemplated herein. For porous low-k dielectric materials, the organic solvent species preferably includes 1-butanol and 1,4-butanediol.

The most preferable cleaning solution for dense dielectrics is a combination of glycols, polar solvent and glycol ether, more preferably, ethylene glycol, tetramethylene sulfone and tripropylene glycol methyl ether or ethylene glycol, tetramethylene sulfone and dipropylene glycol n-butyl ether. The chelating agent(s) may be added to reduce the attack on the metals, e.g., copper and/or cobalt, in the underlying layers.

The chelator/passivation agent in such composition may be of any suitable type, and may include, without limitation, triazoles, such as 1,2,4-triazole, or triazoles substituted with substituents such as C₁-C₈ alkyl, amino, thiol, mercapto, imino, carboxy and nitro groups, such as benzotriazole, tolyltriazole, 5-phenyl-benzotriazole, 5-nitro-benzotriazole, 3-amino-5-mercapto-1, 2, 4-triazole, 1-amino-1, 2, 4-triazole, hydroxybenzotriazole, 2-(5-amino-pentyl)-benzotriazole, 1-amino-1, 2, 3-triazole, 1-amino-5-methyl-1,2,3-triazole, 3-amino-1, 2, 4-triazole, 3-mercapto-1, 2, 4-triazole, 3-isopropyl-1, 2, 4-triazole, 5-phenylthiol-benzotriazole, halo-benzotriazoles (halo ═F, CI, Br or I), naphthotriazole, and the like, as well as thiazoles, tetrazoles, imidazoles, phosphates, thiols and azines such as 2-mercaptobenzoimidizole, 2-mercaptobenzothiazole, 4-methyl-2-phenylimidazole, 2-mercaptothiazoline, 5-aminotetrazole, 5-amino-1,3,4-thiadiazole-2-thiol, 2,4-diamino 6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, mercaptobenzothiazole, imidazoline thione, mercaptobenzimidazole, 4-methyl-4H-1,2,4-triazole-3-thiol, 5-amino-1, 3, 4-thiadiazole-2-thiol, benzothiazole, tritolyl phosphate, indiazole, etc. Suitable chelator species further include glycerols, amino acids, carboxylic acids, alcohols, amides and quinolines such as guanine, adenine, glycerol, thioglycerol, nitrilotriacetic acid, salicylamide, iminodiacetic acid, benzoguanamine, melamine, thiocyranuric acid, anthranilic acid, gallic acid, ascorbic acid, salicylic acid, 8-hydroxyquinoline, 5-carboxylic acid-benzotriazole, 3-mercaptopropanol, boric acid, iminodiacetic acid, etc. Combinations of two or more chelating agents is also contemplated herein. The chelator is usefully employed to increase the compatibility of the composition with the metals and the dielectric materials used in the microelectronic device.

Applying a hydrogen containing plasma to remove the photoresist, followed by applying a wet etch process to remove any remaining residues and the remaining portions of the SLAM, enables those materials to be removed from the surface of a dielectric layer, preferably, a porous dielectric layer. Such a process enables removal of those materials in a relatively fast and inexpensive manner, while preserving the integrity of the etch profile. Also for carbon doped dielectric layer, the process described does not cause depletion of carbon that tends to increase the dielectric constant. The described process also enables the removal of a less porous (or denser) material (e.g., the SLAM) without removing a layer with a higher porosity (e.g., 10-50%) such as the dielectric layer. Barrier layer 102 protects conductive layer 101 from exposure to the materials used to remove the SLAM (FIG. 8). After the wet etch step, the portion of barrier layer 102 that separates via 107 from conductive layer 101 may be removed to expose conductive layer 101—as shown in FIG. 9.

Following that barrier layer removal step, trench 106 and via 107 are filled with second conductive layer 105. Like conductive layer 101, conductive layer 105 preferably comprises copper, and is formed using a conventional copper electroplating process. When an excess amount of the material used to make layer 105 is formed on the surface of dielectric layer 103, one or more CMP steps may be applied to remove the excess material and to planarize the surface of layer 105. When an electroplating process is used to form conductive layer 105 from copper, that CMP step (or steps) removes both the excess copper and the underlying barrier layer.

FIG. 9 shows the structure that results after filling trench 106 and via 107 with a conductive material, then applying a CMP step to remove excess material from the surface of layer 103 to produce conductive layer 105. Although the embodiments shown in FIGS. 1-9 show only one dielectric layer and two conductive layers, the process described above may be repeated to form additional conductive and dielectric layers until the desired integrated circuit is produced.

The improved method for making a semiconductor device of the present invention enables a device that includes a dual damascene interconnect to be made, which integrates a CDO or pCDO containing dielectric layer and a sacrificial light absorbing material. The process of the present invention preserves the via and trench etch profile, while efficiently removing photoresist and SLAM in a relatively inexpensive fashion.

While the invention has been described in terms of several embodiments, those of ordinary skill in the art will recognize that the invention is not limited to the embodiments described. The method and apparatus of the invention can be practiced with modification and alteration within the spirit and scope of the appended claims. The description is thus to be regarded as illustrative instead of limiting.

Having disclosed exemplary embodiments, modifications and variations may be made to the disclosed embodiments while remaining within the spirit and scope of the invention as defined by the appended claims.

We claim:

1. A method of forming a semiconductor device comprising:
forming a conductive layer on a substrate;
forming a porous dielectric layer on the conductive layer;
forming a first etched region by removing a first portion of the porous dielectric layer;
filling the first etched region with a sacrificial light absorbing material;
depositing then patterning a layer of photoresist, after filling the first etched region with the sacrificial light absorbing material, to define a second region to be etched;
forming a second etched region by removing part of the sacrificial light absorbing material and a second portion of the porous dielectric layer;
removing the layer of photoresist; and
selectively etching to remove the remaining portions of the sacrificial light absorbing material using an anhydrous solvent comprising fluoride and a solvent having molecules with at least one —OH group and three to six carbons, wherein the sacrificial light absorbing material is selectively removed over the porous dielectric layer.

2. The method of claim 1, wherein the porous dielectric layer has one or more of a low dielectric constant, carbon doped oxide, and a porosity between about 10-50%.

3. The method of claim 1, further comprises controlling a first etch rate of the sacrificial light absorbing material such that the first etch rate is faster than a second etch rate of the porous dielectric material to provide the selective etching of the sacrificial light absorbing material over the porous dielectric layer.

4. The method of claim 1, wherein the anhydrous solvent is one of a mixture of a primary alcohol and a diol, a mixture of a primary alcohol having four carbons and a diol having four carbons, and a mixture of butanol and butanediol.

5. The method of claim 1, wherein the anhydrous solvent comprises a chelator or a passivation agent.

6. The method of claim 1, wherein the anhydrous solvent has a pH value less than 5.

7. The method of claim 1, wherein removing the layer of photoresist further comprising:
exposing a resulting semiconductor device to a plasma generated from a forming gas, to remove the remaining portions of the photoresist prior to removing the remaining portions of the sacrificial light absorbing material and wherein the forming gas comprises a mixture of hydrogen and a gas selected from the group consisting of nitrogen, helium, argon, krypton, neon, and xenon.

8. The method of claim 1 further comprising:
forming a barrier layer on the surface of the conductive layer prior to forming the dielectric layer;
removing part of the barrier layer after forming the second etched region; and
filling the first and second etched regions with a second conductive layer.

9. A method of forming a semiconductor device having a dual damascene interconnect comprising:
forming a first conductive layer on a substrate;
forming a barrier layer on the surface of the first conductive layer;
forming a porous dielectric layer on the surface of the barrier layer;
patterning a first layer of photoresist, after forming the porous dielectric layer, to define a via;
forming a via through a first portion of the porous dielectric layer;
removing the first layer of photoresist after forming the via;
filling the via with a sacrificial light absorbing layer that comprises a dyed SOG;
patterning a second layer of photoresist to define a trench;
forming a trench within the dielectric layer by removing part of the sacrificial light absorbing layer and a second portion of the porous dielectric layer;
removing the second layer of photoresist after the forming trench; and
selectively etching to remove the remaining portions of the sacrificial light absorbing material using a anhydrous solvent comprising fluoride and a solvent having molecules with at least one —OH group and three to six carbons, wherein the sacrificial light absorbing material is selectively etched over the porous dielectric layer; and
filling the via and trench with a second conductive layer.

10. The method of claim 9, wherein the porous dielectric layer has one or more of a low dielectric constant, carbon doped oxide, and a porosity between about 10-50%.

11. The method of claim 9, further comprises controlling a first etch rate of the sacrificial light absorbing material such that the first etch rate is faster than a second etch rate of the porous dielectric material to provide the selective wet removal of the sacrificial light absorbing material over the porous dielectric layer.

12. The method of claim 9, wherein the anhydrous solvent is one of a mixture of a primary alcohol and a diol, a mixture of a primary alcohol having four carbons and a diol having four carbons, a mixture of butanol and butane diol.

13. The method of claim 9, wherein the anhydrous solvent comprises a chelator or a passivation agent.

14. The method of claim 9, wherein the anhydrous solvent has a pH value less than 5.

15. The method of claim 9, wherein removing the second layer of photoresist further comprising:
exposing a resulting semiconductor device to a plasma generated from a forming gas, to remove the remaining portions of the second layer of photoresist prior to removing the remaining portions of the sacrificial light absorbing material and wherein the forming gas comprises a mixture of hydrogen and a gas selected from the group consisting of nitrogen, helium, argon, krypton, neon, and xenon.

16. The method of claim 9, wherein removing the second layer of photoresist further comprising:
removing a portion of the barrier layer after forming the trench and before filling the via and trench with the second conductive layer.

17. The method of claim 9, wherein the barrier layer comprises a material selected from the group consisting of silicon nitride, silicon carbide, and cobalt, and the first and second conductive layers comprise copper.

18. A method of forming a semiconductor device comprising:
providing a layer of sacrificial light absorbing material formed on substrate, the substrate further comprising a porous dielectric layer;
removing the sacrificial light absorbing material selectively over the porous dielectric layer using a anhydrous solvent comprising fluoride ions, wherein the sacrificial light absorbing material is etched with a controlled etch rate that is faster than an etch rate for the porous dielectric layer; and
controlling the etch rate of the sacrificial light absorbing material by controlling a number of —OH groups and a number of carbons in the anhydrous solvent and a ratio of the anhydrous solvent and the fluoride ions.

19. The method of claim 18, wherein the porous dielectric layer has a higher porosity than a porosity of the sacrificial light absorbing material.

20. The method of claim 18, wherein the anhydrous solvent is one of (a) a mixture of a primary alcohol and a diol; (b) an alcohol solvent containing butanol and butane diol; and (c) a solvent mixture containing a primary alcohol having four carbons and a diol having four carbons.
